(19) United States
(12) Patent Application Publication
(10) Pub. No.: US 2009/0057678 A1
(43) Pub. Date: Mar. 5, 2009

(54) Method of Forming an Integrated Circuit and Integrated Circuit

(76) Inventors: Matthias Goldbach, Dresden (DE); Erhard Landgraf, Dresden (DE); Lars Dreeskornfeld, Dresden (DE)

Correspondence Address: SLATER & MATSIL, L.L.P., 17950 PRESTON ROAD, SUITE 1000, DALLAS, TX, 75252, US

(21) Appl. No.: 11/848,416

(22) Filed: Aug. 31, 2007

(51) Int. Cl. H01L 29/04; H01L 21/8238

(52) U.S. Cl. 257/66; 438/143; 257/E29.003; 257/E21.632

(57) ABSTRACT

A method of forming an integrated circuit, the method including forming at least one patterned gate stack on a substrate including a substrate surface; forming an amorphous substrate region in the substrate by implanting a first material in the substrate; and implanting a getter material to form a getter region within the amorphous substrate region; forming doped implant regions extending from the substrate surface in to the substrate by implanting a second material; and thermally recrystallizing the amorphous substrate region.

### BRIEF DESCRIPTION OF THE DRAWINGS

FIG. 1 illustrates a sectional view of an integrated circuit according to one embodiment;

FIG. 1A illustrates a schematical top view of the integrated circuit of FIG. 1;

FIGS. 2 to 4 illustrate sectional views of an embodiment of an integrated circuit during steps of a method according to one embodiment;

FIG. 4A illustrates a concentration profile of a getter material in a substrate along a lateral direction;

FIG. 4B illustrates an optional thermal treatment step;

FIG. 4C illustrates an optional step of implanting a non-doping material;

FIGS. 5 to 8 illustrate sectional views of an embodiment of an integrated circuit during further steps of the method; and

FIGS. 9A and 9B illustrate an exemplary embodiment regarding the formation of doped implant regions.

### DETAILED DESCRIPTION OF ILLUSTRATIVE EMBODIMENTS

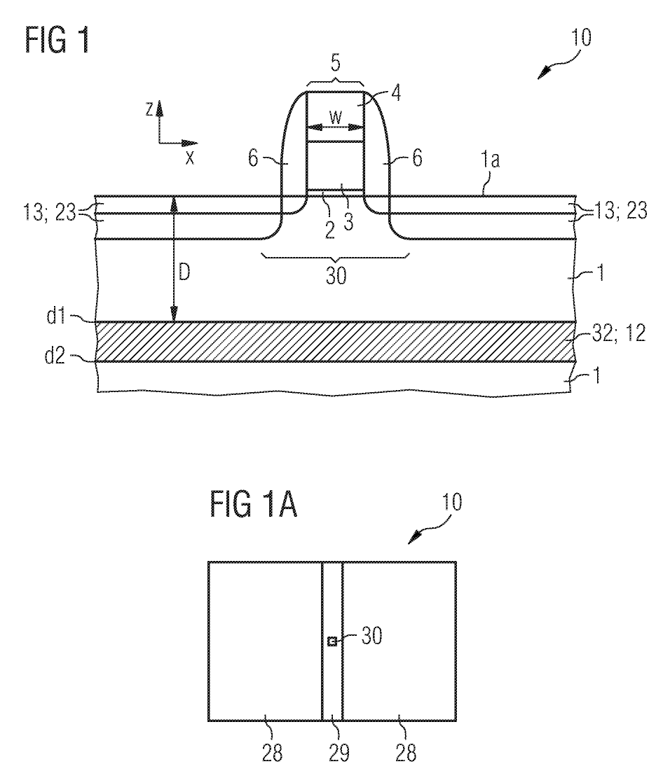

FIG. 1 illustrates an integrated circuit 10 according to one embodiment. In the cross-sectional view of FIG. 1, a substrate 1 comprising a substrate surface 1a is illustrated. The substrate surface 1a may be a main surface of the substrate, that is a surface at which a plurality of transistors and other devices may be formed for obtaining an integrated circuit. The substrate 1 is formed of a substrate material. The integrated circuit 10 comprises at least patterned gate stack 5 arranged on the substrate 1. The integrated circuit 10 further comprises a buried getter layer 32 as well as doped implant regions 23. A transistor 30 may be formed, according to one embodiment, at the at least one patterned gate stack 5.

The patterned gate stack 5 comprises a gate oxide layer 2, at least one conductive gate layer 3 and a gate isolation layer 4. Spacers 6 may be arranged at opposed sidewalls of the patterned gate stack. The patterned gate stack 5 has a width w (of between about 70 nm and about 20 nm, for instance) in lateral direction x. The height of the patterned gate stack (its vertical dimension in direction perpendicular to the substrate surface 1a) may range between about 100 and about 200 nm. However, other dimensions for the width and the height of the patterned gate stack may be used also. The height of the at least one patterned gate stack may be chosen such large that the amorphisation depth in the substrate may be chosen larger without subjecting the gate oxide layer to ion bombardment; the gate oxide layer 2 being protected by layers 3 and 4 from the implanted pre-amophisation material implanted in the substrate with a larger implantation energy.

The integrated circuit according to the embodiment of FIG. 1 comprises a buried getter layer 32 comprising a getter material 12. The buried getter layer 32 is arranged at a distance D from the substrate surface 1a. The buried getter layer 32 may be arranged between a first substrate depth d1 and a second substrate depth d2. The buried getter layer 32 serves to protect substrate material arranged above the getter layer 32 from end-of-range-defects arranged within or beneath (that is deeper than) the getter layer. Furthermore, the buried getter layer 32, in vertical direction, is positioned in the substrate 1 in a depth chosen such that interstitial atoms of the substrate material, which have been dislocated by implantation during formation of the doped implant regions 23, are also arranged within or beneath the buried getter layer 32. Accordingly, the buried getter layer 32 may be arranged comparatively closely to the substrate surface. The distance D between the getter layer 32 and the substrate surface 1a may range, for instance, between about 50 and about 300 nm. However, other dimensions may be used also. The buried getter layer 32 may for instance comprise carbon C as the getter material 12. Alternatively, the buried getter layer 32 may comprise oxygen or fluorine as the getter material 12. However, other materials may also be used as the getter material 12.

The integrated circuit 10 comprises doped implant regions 23 on opposed sides of the patterned gate stack 5. The doped implant regions 23 may be, for instance, source/drain implant regions, or lightly doped drain regions (LDD-regions; that are regions of same dopant type but having a smaller depth of the dopant profile compared to source/drain implant regions), or contact implant regions. In particular, the doped implant regions 23 may comprise one or more of these kinds implant regions. For instance, in FIG. 1 shallower LDD-regions (extending below the spacers 6) as well as slightly deeper source/drain implant regions are illustrated. Any atoms of the substrate material dislocated from their original position, upon implantation of the second material 13 which forms the doped implant regions, are arranged within the buried getter layer 32 or beneath the buried getter layer 32. Accordingly, the buried getter layer 32 is separating the active area of the transistor 30 and the substrate material arranged above the buried getter layer from any interstitial substrate material atoms. Thereby leakage currents are reduced significantly. The integrated circuit 10 of FIG. 1 may be any integrated circuit in which transient enhanced diffusion (TED) is to be reduced. For instance, the integrated circuit 10 may be a logic circuit or a memory device. The integrated circuit 10 may comprise a support region for a memory array or for any other integrated circuit region.

Throughout the present application, the same respective reference signs will be used for denoting any element illustrated in the Figures.

FIG. 1A schematically illustrates a schematical top view on an example of an embodiment of an integrated circuit 10. The integrated circuit 10 may comprise at least one transistor 30 formed at least one gate stack. The at least one transistor 30 formed at the at least one gate stack may be provided in a logic circuit 29 of the integrated circuit 10, for instance.

The integrated circuit 10 may be any kind of integrated circuit, for instance a logic integrated circuit. The integrated circuit 10 may comprise the logic circuit 29 but may also comprise at least one further circuit region. For instance, the integrated circuit 10 may also comprise at least one memory array 28. The logic circuit 29 may, for instance, be a support region or periphery region for at least one memory array 28. However, the integrated circuit 10 need not be a memory device. Instead, the integrated circuit 10 may also be a logic integrated circuit.

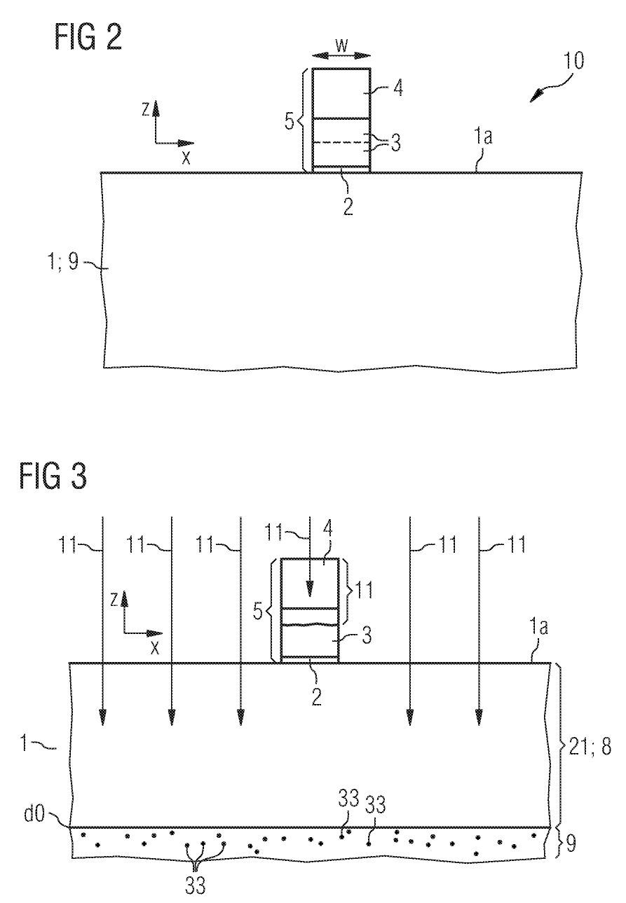

FIGS. 2 to 8 illustrate an embodiment of a method for forming an integrated circuit. According to FIG. 2 at least one patterned gate stack 5 is formed on a substrate 1. The substrate 1 may be a semiconductor substrate. The substrate 1 comprises a substrate material, like a semiconductor material. The substrate comprises a substrate surface 1a on which the at least one patterned gate stack 5 is formed.

As apparent from FIG. 2, a gate oxide layer 2 is formed on the substrate surface 1a and at least one conductive gate layer 3 is formed on the gate oxide layer 2. Furthermore, a gate isolation layer 4 is formed on the conductive gate layer 3. Subsequently, at least the gate isolation layer 4 and the conductive gate layer 3 are patterned, thereby obtaining at least one patterned gate stack 5 comprising the gate oxide 2, the conductive gate layer 3 and the gate isolation layer 4 above the substrate surface 1a. The gate oxide layer may be formed of silicon dioxide, for instance, and the conductive gate layer may include a polysilicon layer, for instance, or, alternatively or in addition, a metal layer. However, any other kinds of materials may be used also. The thickness of the at least one conductive gate layer 3 may be chosen between about 50 and about 200 nm, like about 100 nm for instance. However, another amount of thickness may be used instead. The at least one conductive gate layer 3 may include a polysilicon layer and a metal layer arranged above the polysilicon layer, both layers having a thickness of about 50 nm, for instance. However, other numerical thickness values may be used also. The gate isolation layer 4 may be a silicon nitride layer and may have a thickness of between about 50 and about 200 nm, for instance of about 100 nm. However, another amount of thickness may be used also. By patterning at least the layers 4 and 3, a patterned gate stack having a width w is obtained. The width w of the at least one patterned gate stack 5 may range between 25 nm and 100 nm, for instance. However, another amount of the width w outside this range may be used also. As apparent from FIG. 2, the material of the substrate 1 may be a crystalline substrate material 9.

As illustrated in FIG. 3, a first material 11, like germanium, silicon, argon, krypton, or xenon, for instance, or any other material which does not form n-doped or p-doped substrate regions in the substrate, may be implanted into the substrate. Implantation may be performed along the negative vertical direction—z, for instance. Implantation of the first material 11 serves to amorphise the crystalline substrate material 9 (FIG. 2), thereby obtaining amorphous substrate material 8 at least in a region between the substrate surface 1a and an amorphisation depth d0. For instance, the amorphisation depth d0 may be larger than twice the width w of the patterned gate stack 5 and preferably may range between four times and eight times the width of the patterned gate stack 5. For instance, one of germanium, silicon, argon, krypton, or xenon, for instance, (or any other material which does not form n-doped or p-doped substrate regions) may be implanted into the substrate, for instance, to a maximum depth of about 150 nm. The implantation dose of the first material, like germanium, for instance, may be chosen between 10¹³ and 10¹⁶ atoms/cm², preferably between 10¹⁴ and 5×10¹⁴/cm². The implantation energy may be chosen between about 50 and about 250 keV, for instance. Due to the circumstance that the amorphisation depth d0 may be at least larger than twice the width w of the patterned gate stack 5, for instance, the amorphised region of amorphous substrate material 8 is completely shielding the bottom surface of the patterned gate stack from non-amorphised, crystalline substrate material 9 maintained beneath the amorphisation depth. In particular, at least in a substrate depth close to (but smaller than) the amorphisation depth d0, the substrate material shadowed by the patterned gate stack 5 (that is substrate material which is arranged at the same lateral position in lateral direction x as the gate stack 5) is amorphised or at least free from end-of-range-defects. End-of-range-defects are defects in a crystal lattice resulting from partial amorphisation of a previously monocrystalline substrate material. In a monocrystalline substrate, a monocrystalline crystal lattice formed of the atoms of the substrate material is present. Upon amorphisation of a part of the substrate (like the substrate region between the substrate surface 1a and the amorphisation depth d0 in FIG. 3), in the non-amorphised substrate region close to the phase boundary between the crystalline phase and the amorphous phase, a plurality of crystal defects occur in the non-amorphised substrate material. Such end-of-range-defects, if arranged close to an active area (like a channel region or the source/drain regions of a transistor, for instance) may produce leakage currents deteriorating transistor performance, in particular when approaching the substrate surface. In FIG. 3, however, all end-of-range-defects 33 are arranged at a distance from the substrate surface 1a which distance is at least equal to or larger than d0 representing the amorphisation depth.

In FIG. 3 an upper portion of the patterned gate stack 5 may also be amorphised. For instance, the gate isolation layer 4 and an upper portion of the at least one conductive gate layer 3 may be amorphised. However, the gate oxide layer 2 preferably is protected from ion bombardment by means of the at least one conductive gate layer 3 and the gate isolation layer 4 arranged on top of the gate oxide layer 2.

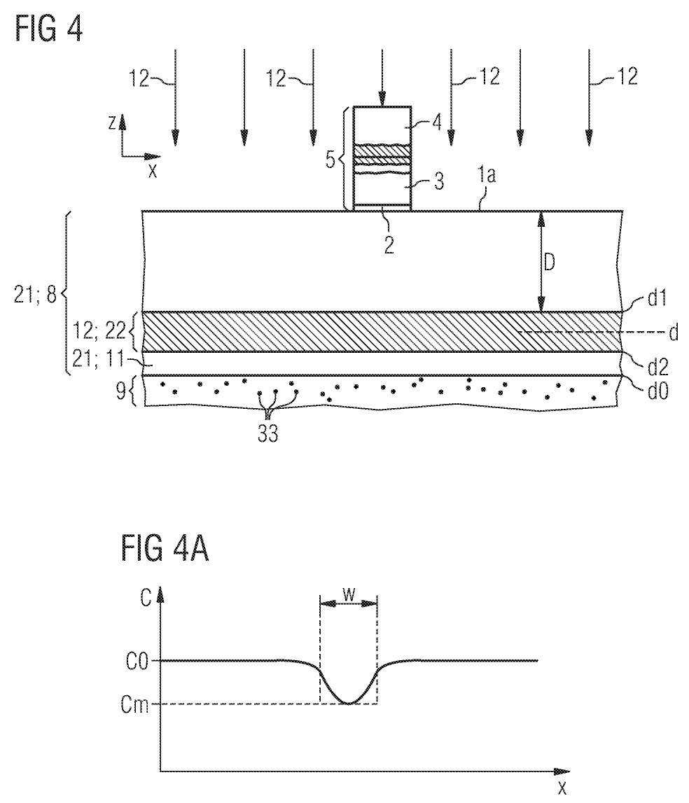

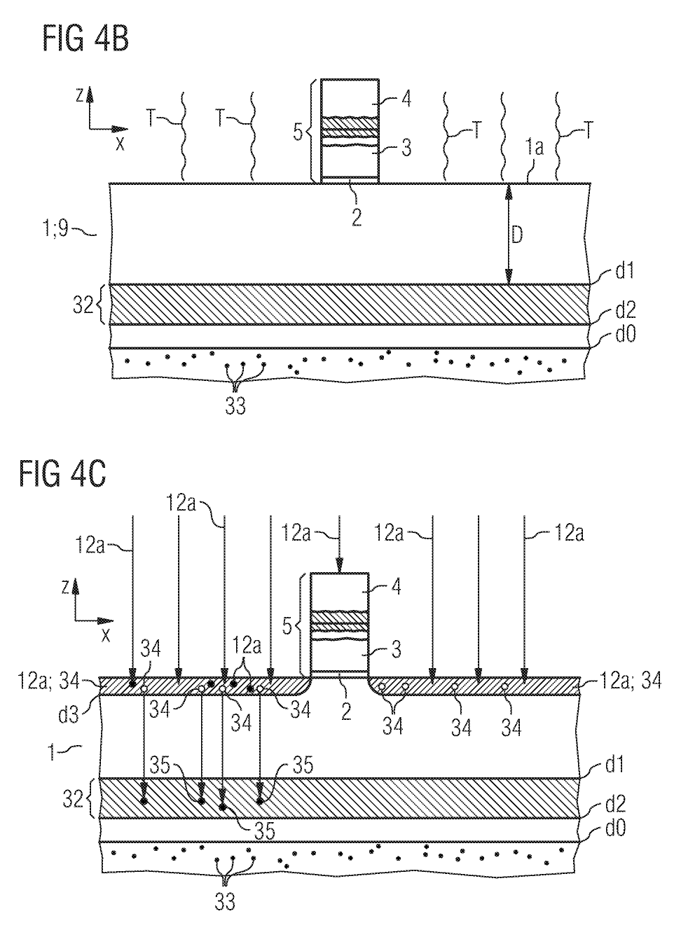

According to FIG. 4, a getter material 12 is implanted into the substrate. The getter material may be carbon. Alternatively, the getter material may be oxygen or fluorine. Alternatively, other materials may be chosen also. The material in the substrate may be densified to some extent by implanting the getter material 12. The getter material 12 is implanted into the substrate 1 in a substrate depth ranging between a first substrate depth d1 and a second substrate depth d2. Thereby the getter material 12 is implanted such that it is arranged at a distance D from the substrate surface 1a. The first depth d1 (corresponding to the minimum depth of the getter material 12 implanted or otherwise introduced in the substrate) is smaller than the amorphisation depth d0. Furthermore, also the second substrate depth d2 (corresponding to the maximum depth of the getter material 12) may also be smaller than the amorphisation depth d0. Accordingly, preferably all getter material 12 is implanted into a portion of the amorphous substrate region 21 as illustrated in FIG. 3. The getter material 12 forms a getter region 22 (between the first depth d1 and the second depth d2) in which the substrate material (like a semiconductor material, for instance) additionally comprises the getter material 12. In a later step of the present embodiment of the method, the getter region (denoted with 22 in FIG. 4) comprising the getter material 12 will form, after a thermal treatment, a buried getter layer 32 (FIGS. 4B and 5). The buried getter layer 32 is shielding the substrate material arranged above the buried getter layer 32 from any interstitial atoms originating from end-of-range-defects 33 arranged within or beneath the getter layer 32. At the stage of the method illustrated in FIG. 4, however, the substrate material of the amorphous substrate region 21 and of the getter region 22 (arranged within the amorphous substrate region 21) is still amorphous (as indicated by reference number 8). Accordingly, implantation of the first material 11 in FIG. 3 achieves a pre-amorphisation (for instance prior to implantation of the getter material and to further processing steps explained herein below).

The getter material 12 may be implanted in a depth between about d1=50 nm and about d2=300 nm, for instance. The first substrate depth d1 may range between a depth at least as large as the width w of the patterned gate stack 5 (for instance larger than twice the width w) and a depth smaller than six times the width w of the patterned gate stack. The getter material in particular may be carbon implanted with a dose of between about 10¹⁴ and about 10¹⁵ atoms per cm². The implantation energy may be chosen between about 20 and about 30 keV, for instance. However, other numerical ranges, dimensions and materials may be chosen also. The getter material 12, in like manner as the first material 11, may be implanted in direction perpendicular to the substrate surface, for instance.

FIG. 4A illustrates a concentration profile of a concentration C of the getter material 12 in the substrate, taken along lateral direction x, at a substrate depth d (FIG. 4). The depth d represents the depth of maximum concentration of the getter material 12 in vertical direction perpendicular to the substrate surface 1a. The depth d is larger than the first depth d1 but smaller than the second depth d2. FIG. 4A illustrates the profile of the concentration C of the getter material 12, in lateral direction x, depending on the lateral position in the substrate 1. As apparent from FIG. 4A, laterally outside the patterned gate stack 5 (having a width w), the concentration of the getter material in the depth d substantially corresponds to a maximum concentration CO. In a substrate region shadowed by the patterned gate stack 5 and substantially corresponding to the width w of the patterned gate stack 5, the concentration C of the getter material 12 is reduced. In the centered region below the patterned gate stack 5, the concentration of the getter material 12 has a local minimum Cm. However, the concentration of the getter material at the local minimum Cm is finite, that is larger than zero. Accordingly, although the concentration C of the getter material 12 is, to some degree, reduced in the centered region below the patterned gate stack, the getter region 22 (comprising the getter material 12 implanted into the substrate material) is continuous (rather than interrupted) below the patterned gate stack 5 since the concentration of the getter material 12 (like carbon for instance) is merely reduced to the local minimum Cm (in lateral direction) but is not zero. The getter region 22 formed by the implanted getter material 12 thus completely separates the upper part of the substrate (arranged in a depth smaller than the first substrate depth d1) from any end-of-range-defects 33 which might be present in the non-amorphised substrate material 9 below the amorphisation depth d0. The depth d or the minimum depth d1 of the getter region 22 comprising the getter material may be chosen, for instance, between twice the width of the patterned gate stack 5 and six times the width w of the patterned gate stack 5, for instance. As in FIG. 3, also in FIG. 4, the gate oxide layer 2 is protected from implantation (of the getter material 12) by the at least one conductive gate layer 3 and by the gate isolation layer 4.

FIG. 4B illustrates an optional thermal treatment step. Accordingly, after the method step of FIG. 4, the method may be continued with the method step of FIG. 4B (before being continued with FIG. 5, for instance). Alternatively, however, after the method step of FIG. 4, the method may also be continued with the method step of FIG. 5 directly.

As illustrated in FIG. 4B, the amorphised substrate material 8 may be subjected to a thermal treatment T and thereby converted, by solid phase epitaxial regrowth, into crystalline substrate material 9. This (first) thermal treatment T is recrystallizing the substrate material 8 (FIG. 4) in the amorphised substrate region 21 (FIG. 4) including the getter region 22, beginning from the phase boundary in the depth d0 (corresponding to the former amorphisation depth) and proceeding in direction towards the substrate surface 1a. During recrystallization, any first material 11 (like germanium, silicon, argon, krypton, or xenon, for instance, or any other appropriate material which does not form n-doped or p-doped substrate regions in the substrate) and any getter material (like carbon, oxygen, or fluorine, for instance, or any other getter material) is bound at fixed positions within the crystal lattice. In general, the buried getter layer 32 suppresses transient enhance diffusion (TED) of interstitial atoms (like dopant atoms, for instance) which could otherwise occur during the thermal treatment. In particular, by recrystallizing the amorphous substrate material in the getter region 22 where the getter material 12 has been implanted, a buried getter layer 32 is formed.

In particular, when recrystallizing the getter region 22 (FIG. 4) which comprises, in addition to the amorphous substrate material 8 and the first material 11, the getter material 12 (like carbon, for instance), a buried getter layer 32 (FIG. 4B) is formed of the getter region 22 (FIG. 4); the buried getter layer 32 now shielding the upper region of the substrate from any interstitial atoms (originating from end-of-range-defects 33 arranged within or beneath the buried getter layer 32). Thereby any interstitial atoms originating from end-of-range-defects 33 yet arranged below the buried getter layer 32 will no longer be able to diffuse in the direction of the substrate surface 1a and to produce any leakage currents or to cause transient enhanced diffusion (TED) in the integrated circuit. After the thermal treatment, the buried getter layer 32 comprises a monocrystalline crystal lattice in which atoms of the getter material 12 are arranged on (rather than between) the lattice sites of the monocrystalline lattice.

The thermal treatment T in FIG. 4B may be performed at a temperature less than about 800° C., for instance at a temperature between about 600 and about 800° C. and for about 10 to about 30 minutes, for instance.

After the additional, optional thermal treatment step of FIG. 4B, or, alternatively, directly after the step of FIG. 4, the method may be continued with further method steps illustrated in FIG. 5, etc., for implanting the doped implant regions.

As illustrated in FIG. 4C, a non-doping material 12a may optionally be implanted closely below to the substrate surface 1a (for instance to a depth of less than about 20 or less than about 10 nm in the recrystallized substrate material), thereby generating a large concentration of vacancies (free lattice sites on which no atom is resident in the crystal lattice). The non-doping material, fluorine or silicon may be implanted, for instance. However, any other non-doping material may be used for generating vacancies in the substrate closely below the substrate surface. By implantation of the non-doping material 12a, vacancies 34 (close to the substrate surface) and interstitials 35 (deeper in the substrate; within or below the getter layer 32) are formed. When subsequently implanting the second material 13 (like p-dopants and/or n-dopants), a high extent of activation is achieved easily due to the large concentration of vacancies already present closely below the substrate surface.

According to FIG. 5, a second material 13 is implanted into the substrate 1 to form rather shallow, doped implant regions 23 in a substrate region close to the substrate surface 1a.

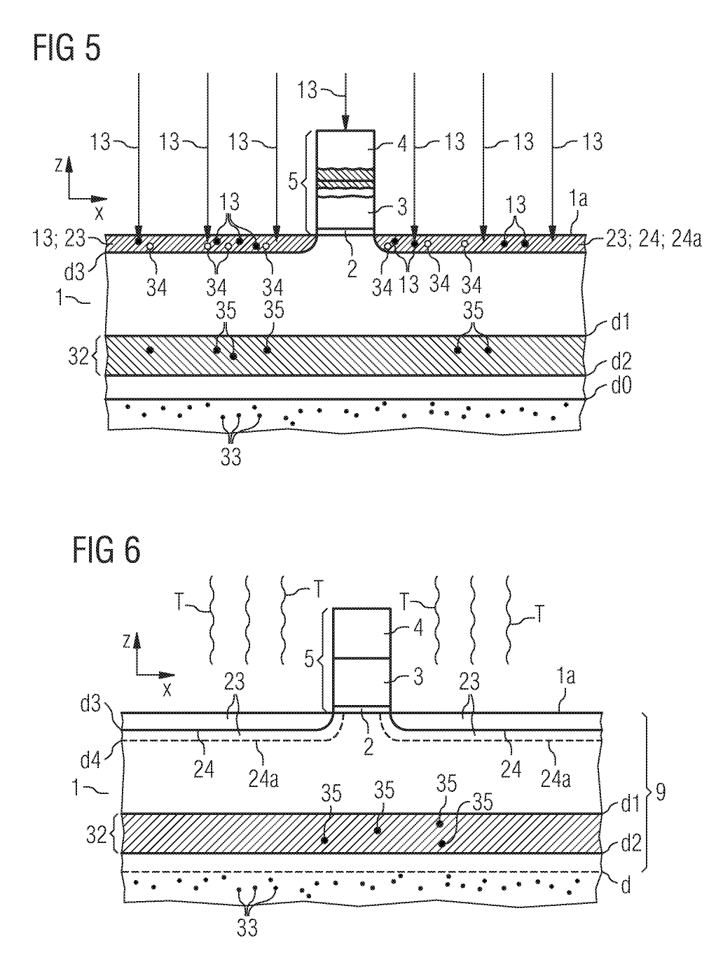

The second material 13 is implanted below the substrate surface 1a, extending from the substrate surface 1a to a substrate depth d3 smaller than a depth of the getter region 22. For instance, shallow doped implant regions 23 with a depth of between about 2 and about 10 nm and with a high degree of dopant activation can be obtained. In particular when the non-doping material 12a has been implanted in the step of FIG. 4C, a very high degree of activation of the implanted second material 13 is obtained in FIG. 6 and a very low thermal budget may be sufficient in a subsequent thermal treatment (FIG. 6) for activating all remaining implanted second material 13.

As the second material 13, boron or phosphorus may be implanted, for instance. According to one embodiment illustrated in FIG. 5, for instance LDD-regions (Lightly Doped Drain regions) 24 may be formed as the doped implant regions 23. Alternatively or in addition thereto, pocket implant regions 24a may be formed.

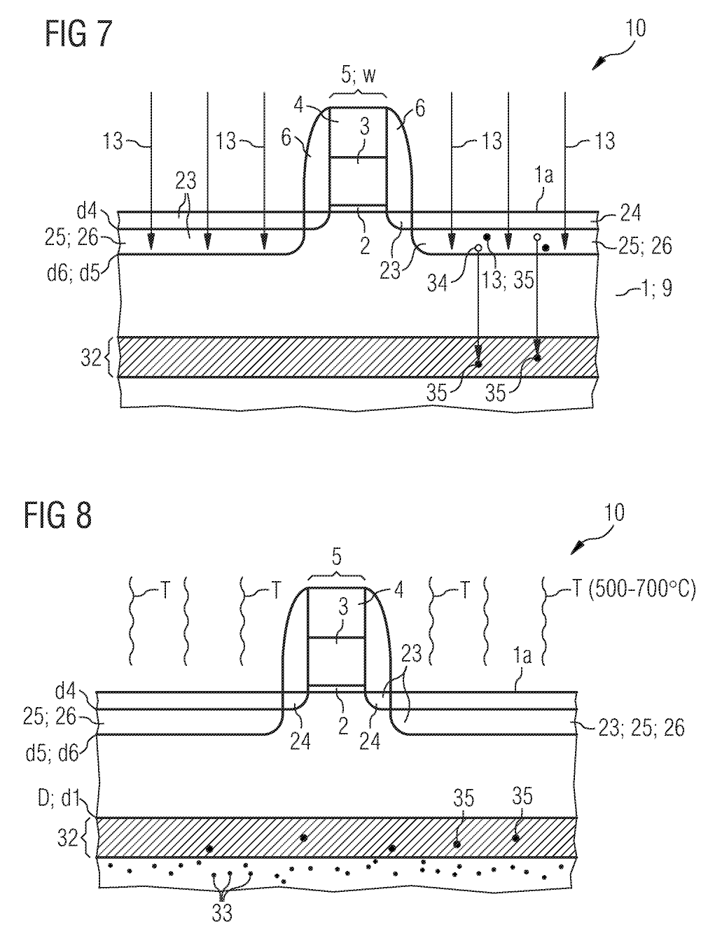

The doped implant regions 23 may comprise at least one of lightly doped drain regions 24, pocket implant regions 24a, source/drain implant regions 25 (FIG. 7), or contact implant regions 26 (FIG. 7).

Generally, the second material 13 is implanted into the substrate on both opposed sides of the gate stack 5. According to one embodiment, a transistor may be formed at the gate stack 5; the conductive gate layer 3 serving as a gate electrode of the transistor. The transistor to be formed may be the transistor of a logic circuit. The logic circuit, for instance, may be a periphery circuit of a memory device. Alternatively, the whole integrated circuit 10 may be a logic integrated circuit.

In FIGS. 4C and 5, the implantation of the non-doping material 12a and/or of the second material 13 into the substrate can be performed such that atoms of the substrate material which are dislocated, that is, pushed away from their original position in the substrate, become resident in a deeper substrate region which is arranged within or below the buried getter layer 32 comprising the getter material 12. Accordingly, no interstitials are produced in the substrate regions between the doped implant regions 23 and the buried getter layer 32. Only the dopant atoms of the second material 13 implanted in the doped implant regions 23 may become interstitial atoms arranged at positions between the lattice sites of the crystal lattice within the doped implant regions 23.

Since a large number of vacancies 34 may be formed in the crystal lattice by implanting the non-doping material 12a in FIG. 4C (before implanting the second material 13 in FIG. 5), only a small amount of heat may will be subsequently required for achieving recombination of remaining interstitial atoms of the second material 13 with the vacancies 34 in the doped implant regions 23.

Furthermore, due to the implantation energy chosen, all dislocated atoms of the substrate material (pushed from their original positions within the area of the doped implant regions 23 produced) will be transferred to positions at a substrate depth larger than the first depth d1 at which the buried getter layer 32 comprising the getter material 12 is present.

In the buried getter layer 32 formed after the respective first thermal treatment (that is after recrystallisation), the implanted getter material is substituting atoms of the substrate material 9 on the crystal lattice sites. Such a substitutional buried getter layer 32 very efficiently prevents diffusion of end-of-range-defects 33 and interstitials 35 and captures them in locally bound positions.

Since the thermal treatment of FIG. 4B need not be performed, the second material 13 may also be implanted into the non-crystallized, amorphous substrate material 8, directly after the process step of FIG. 4 (or after having performed the steps of FIGS. 4 and 4C without having performed the step of FIG. 4B). In particular when the step of FIG. 5 is performed directly after the step of FIG. 4, the substrate material 8 is still amorphous when the second material 13 is implanted therein.

Alternatively, for forming vacancies in the recrystallized substrate material 9 before implanting the second material 13 for the doped implant regions, the steps of FIGS. 4B and 4C may be performed after the step of FIG. 4, prior to the step of FIG. 5. When the second material 13 is then implanted in FIG. 5, a comparatively high amount of the second material 13 will be activated due to the presence of vacancies 34 formed in the step of FIG. 4C. Furthermore, only a comparatively low thermal budget will be required in a subsequent thermal treatment step (like FIG. 6 or FIG. 8, for instance) for completely activating all implanted second material 13 in the doped implant regions 23.

As illustrated in FIG. 6, the substrate may be subjected to a thermal treatment. In case that no previous thermal anneal step of FIG. 4B has been executed, the thermal treatment step of FIG. 6 serves to recrystallize the substrate and to form the buried getter layer 32 by crystallizing the substrate material comprising the getter material.

Alternatively, in case that the previous thermal treatment according to FIG. 4B has already been performed (such that the substrate is already recrystallized); the thermal treatment of FIG. 6 may serve to activate the dopants of the second material 13 in the doped implant regions 23. A rather low amount of heat is then required in order to activate a large amount of doped atoms (like B or P) since, due to the large concentration of vacancies 34 in the doped implant regions 23 and of atoms of the second material 13 (B or P) arranged at interstitial positions between the lattice sites in the doped implant regions 23, recombination of plural vacancies 34 and interstitials 35 with one another is obtained easily. Due to the large concentration of vacancies and of dopant atoms of the second material 13 closely below the substrate surface, a lower temperature and less amount of heat is required in order to activate the dopant atoms of the second material 13 within the doped implant regions 23. Furthermore, a very high degree of activation of the second material 13 and a steeper doping profile are achieved. In particular, very shallow doped implant regions 23 may be formed with less thermal budget than in prior art and with steeper gradients of dopant concentration between the doped implant regions 23 and the substrate regions material below the doped implant regions 23.

Furthermore, any interstitial atoms of substrate material dislocated (pushed off) from their original position within the doped implant regions 23 will occupy positions at substrate depths deeper than the first substrate depth d1. Accordingly, they will be gettered in fixed positions within or beneath the buried getter layer 32. Accordingly, in the substrate region between the substrate depth d1 and the substrate surface 1a, the concentration of maintained interstitial atoms of substrate material which might contribute to leakage currents is reduced.

The (second) thermal treatment T illustrated in FIG. 6 may be performed at a temperature below about 700° C., for instance at a temperature between about 500° C. and about 700° C.

As outlined above, plural effects with regard to the doping profiles and the positions of any maintained interstitial atoms and end-of-range-defects may be achieved combinedly with one another according to this and further embodiments. Furthermore, it is to be noted that, irrespective of the particular example of FIG. 5 in which the doped implant regions 23 formed by the second material 13 are lightly doped drain regions 24, alternatively the doped implant regions 23 may also be source/drain implant regions 25 or contact implant regions 26 or pocket implant regions 24a. Furthermore alternatively, these embodiments may be combined with one another. In particular, source/drain implant regions 25 may be formed in addition to the lightly doped drain regions 24 of FIG. 5, as will be explained herein below with reference to FIG. 7.

As in FIG. 6, ultra-shallow junctions and improved activation of the dopants are achieved with less amount of heat necessary.

Optionally, as illustrated in FIG. 7, the method may be prosecuted with further implanting the second material 13 for additionally forming further doped implant regions 23, like source/drain implant regions 25 and/or contact implant regions 26. As in FIG. 5, boron B or phosphorus P may be used as the second material 13, for instance. Preferably, prior to performing the implantation according to FIG. 7, spacers 6 may be formed on opposed sidewalls of the at least one patterned gate stack 5. Subsequently, the implantation is performed, thereby forming, for instance, source/drain implant regions 25 and/or contact implant regions 26. Again, a step of generating vacancies 34 by first implanting a non-doping material 12a (like in the step of FIG. 4B) may be executed prior to implanting the second material 13 in FIG. 7 (that is between the steps of FIG. 6 and FIG. 7). The atoms of the second material 13 implanted according to FIG. 7 (and/or the non-doping material implanted before) again may cause vacancies 34 in the respective doped implant regions 23, 25, 26. Furthermore, atoms of the substrate material dislocated from their former position in the doped implant regions 23 may produce interstitials 35 in a larger substrate depth. However, the implantation in FIG. 7 (and in the preceding, optional step of implanting the non-doping material 12a) may be performed such that all interstitials 35 formed by dislocation of substrate material atoms become resident within or beneath the buried getter layer 32 comprising the getter material 12. The getter layer 32 again protects the active area from such interstitials. Furthermore, due to the large concentration of lattice site vacancies 34 and of interstitial atoms of the second material 13 within the newly formed doped implant regions 23; 25, 26, again a rather small amount of heat is required to place the dopant atoms of the second material 13 at the vacancies 34 and thereby activating the second material 13.

The further (third) thermal treatment T is illustrated in FIG. 8. The thermal treatment T may be performed at a temperature below about 700° C., for instance at a temperature between about 500° C. and about 700° C. After this thermal treatment T, all second material present in the doped implant regions 25; 26 is activated (like previously occurred with the second material 13 in FIG. 6). Furthermore, no further interstitial atoms become resident in the upper substrate region between the first substrate depth d1 of the getter layer 32 and the substrate surface 1a. Instead, most of interstitial atoms 35 originating from end-of-range-defects 33 have already been gettered in the getter layer 32 or trapped in a substrate region deeper than the getter layer 32 before during recrystallisation by the first thermal treatment.

Accordingly, very shallow and highly activated doped implant regions 23 are obtained without the need to apply excessive heat application. For instance, for forming contact implants a large amount of dopants of the contact implant regions 26 is efficiently activated without the need to heat the substrate above about 700° C. Furthermore, in case that the integrated circuit comprises a memory array, a final furnace anneal (FFA) may be replaced with the thermal anneal T of FIG. 6 and/or with the thermal treatment T of FIG. 8 which render superfluous any additional thermal treatment performed at a later stage of the proceedings. Accordingly, no additional thermal treatment will be required after formation of the source/drain implant regions 25 (HDD; highly doped drain regions) which might undesirably deactivate part of the activated dopant atoms.

As will become apparent from embodiments disclosed herein, a very effective engineering of dopant profiles and defect distributions is obtained. In particular, end-of-range-defects 33 as well as interstitials 35 are kept away from an upper substrate area arranged between the buried getter layer 32 and the substrate surface 1a. Furthermore, highly activated doped implant regions 23 are formed easily which do not generate any interstitials 35 above the getter layer 32. Due to the high amount of activated dopant atoms of the second material 13, steeper flanks of a dopant profile of the second material 13 are obtained. Accordingly, a large amount of the super-saturated dopant atoms of the second material 13 within the shallow doped implant regions 23 is easily activated by the vacancies 34 generated in the doped implant regions 23. There are no defects generated in the space charge regions around the doped implant regions 23. In particular, in case that a transistor is formed at the patterned gate stack 5, leakage currents are reduced significantly and transient enhanced diffusion (TED) is suppressed.

The recrystallized substrate region remains free from end-of-range-defects 33 and interstitials 35 and the buried getter layer 32 protects and separates the substrate region above the buried getter layer 32 from end-of-range-defects 33.

Of course, the consecutive order of measures for performing the method may be altered. For instance, the consecutive order of implanting the second material 13, of implanting a getter material 12 and of performing the thermal recrystallizing may be reversed in arbitrary manner. For instance, the second material 13 may be implanted after the thermal anneal, optionally followed by a further anneal.

Furthermore, the getter material 12 may be implanted prior to implanting the first material 11 causing amorphisation. The thermal anneal and the implantation of the second material 13 may than follow in arbitrary temporal order.

Furthermore, gate stack formation and getter material implantation may be performed first, prior to amorphisation. The thermal anneal and the implantation of the second material may than follow in arbitrary consecutive order.

These and further exemplary embodiments regarding the consecutive order of the method steps are claimed in the appended claims.

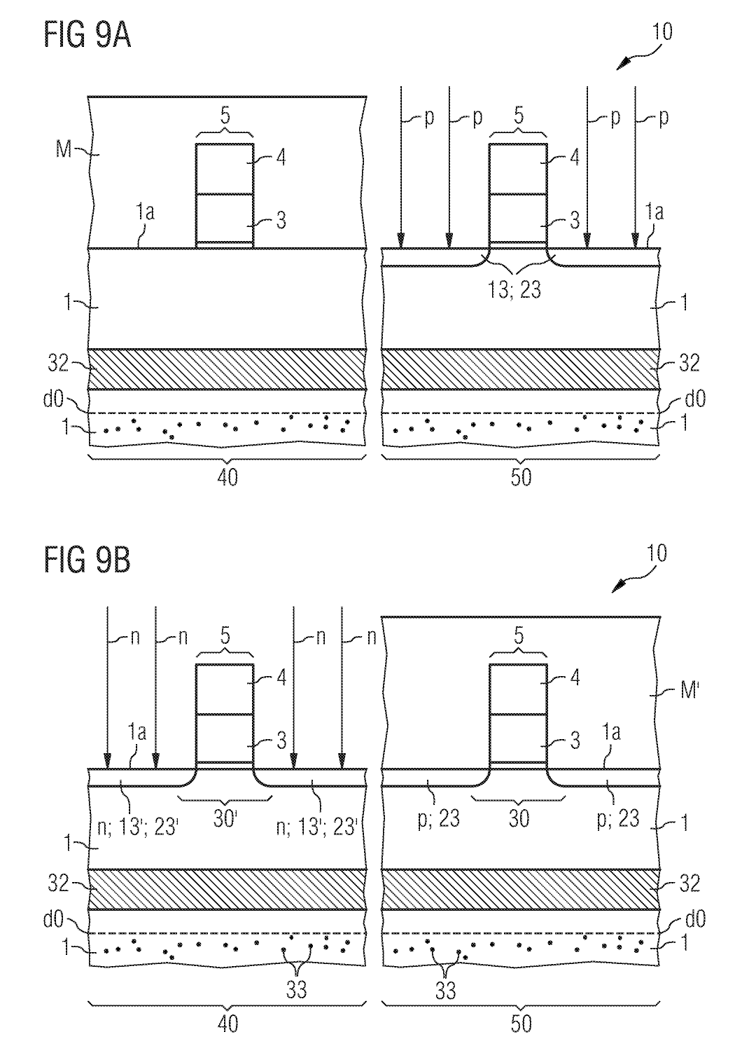

FIGS. 9A and 9B illustrate one embodiment of implanting the second material 13 which may comprises at least one of a p-dopant p and an n-dopant n, like boron and phosphorus, for instance. At each patterned gate stack 5 on the substrate 1, one transistor may be formed by means of implanting the second material 13.

For each transistor to be formed at a respective gate stack the doped implant regions 23 may be provided on both opposed sides of the respective patterned gate stack 5.

As illustrated in FIGS. 9A and 9B, at least two patterned gate stacks (or, in general, a plurality of first gate stacks and a further plurality of second gate stacks) may be formed on the substrate for obtaining a CMOS circuit, for a logic region for instance, the semiconductor device 1 comprising a first substrate region 40 and a second substrate region 50 each supporting at least one respective gate stack. For each type of doped implant regions 23 to be implanted (like source/drain implant regions 25, contact implant regions 26, lightly doped drain regions 24, or pocket implant regions 24a; see FIGS. 5 to 8), two respective implantation steps may be performed, each implantation step implanting dopants in one respective (first or second) substrate region 40 or 50 and both respective implantation steps combinedly constituting a step of implanting the second material into the substrate. The second material 13 accordingly comprises at both a p-dopant p and an n-dopant n, like boron and phosphorus, for instance, wherein on each of both substrate regions 40, 50 one of both dopant types is implanted.

Accordingly, the second material 13 comprises both the p-dopant p and the n-dopant n implanted. Thereby a CMOS integrated circuit can be formed.

For instance, as illustrated in FIG. 9A, the first substrate region 40 may be a mask M may be formed on the first substrate surface region 40 prior to implanting one of the p-dopant and the n-dopant into the second substrate region 50 different from the first substrate surface region 40. In the example of FIG. 9A, for instance a p-dopant is implanted into the second substrate region 50. For instance, p-doped source/drain-regions of a p-MOSFET may be implanted or otherwise introduced. Subsequently, the mask M may be removed from the first substrate surface region 40.

As illustrated in FIG. 9B, after removal of the mask M from the first substrate region 40, a further mask M′ is formed on the second substrate region 50 and the other one of the p-dopant and the n-dopant is implanted into the first substrate regions 40. In the example of FIG. 9B, for instance an n-dopant is implanted into the first substrate region 40. For instance, n-doped source/drain-regions of an n-MOSFET may be implanted or otherwise introduced. Finally, the further mask M′ may be removed from the first second surface region 50.

By this manner, any type of doped implant regions 23 may be formed in both substrate regions 40, 50 and may thus comprise dopants of both dopant types, each type implanted in a respective one of the first and second substrate region 40, 50. Thereby, a CMOS circuit may be formed.

What is claimed is:

1. A method of forming an integrated circuit, the method comprising:
forming at least one patterned gate stack on a substrate comprising a substrate surface;
forming an amorphous substrate region in the substrate by implanting a first material in the substrate;
implanting a getter material to form a getter region within the amorphous substrate region;
recrystallizing the amorphous substrate region by a thermal treatment; and
forming doped implant regions extending from the substrate surface into the substrate by implanting a second material.

2. The method of claim 1, wherein the amorphous substrate region extends from the substrate surface to an amorphisation depth in the substrate.

3. The method of claim 1, further comprising, prior to implanting the second material, implanting a non-doping material, thereby forming vacancies in substrate regions where the doped implant regions are to be formed.

4. The method of claim 1, wherein the getter region is arranged deeper in the substrate than a first depth, the first depth being larger than twice a width of the patterned gate stack.

5. The method of claim 4, wherein the getter region is arranged between the first depth and a second depth, the second depth being smaller than the amorphisation depth of the amorphous substrate region.

6. The method of claim 5, wherein a substrate material in an area located in a laterally centered position beneath the patterned gate stack, at least in a depth close to but smaller than the second depth, is amorphised by implanting the first material.

7. The method of claim 1, wherein the first material comprises a material that does not form n-doped or p-doped areas in the substrate.

8. The method of claim 1, wherein the getter region comprising the getter material forms a buried layer continuously extending in a lateral direction, without interruption, beneath the patterned gate stack.

9. The method of claim 1, wherein the buried layer, laterally outside the patterned gate stack, comprises a maximum concentration of the getter material and, in a centered region passing beneath the patterned gate stack, comprises a concentration of the getter material smaller than the maximum concentration of the getter material but larger than zero.

10. The method of claim 1, wherein amorphised substrate material is recrystallized into crystalline substrate material by the thermal treatment.

11. The method of claim 10, wherein the maximum concentration of the getter material is chosen such that the getter material is completely soluble in the recrystallized substrate material, the maximum concentration preferably being smaller than 3% per weight of the substrate material.

12. The method of claim 10, wherein the maximum concentration of the getter material is chosen between 1×10¹⁹/cm³ and 5×10²⁰/cm³.

13. The method of claim 1, wherein carbon is implanted as the getter material.

14. The method of claim 1, wherein oxygen or fluorine is implanted as the getter material.

15. The method of claim 14, wherein the second material is implanted into the amorphized substrate material.

16. The method of claim 3, wherein the second material is implanted into the substrate material after at least one of recrystallizing the substrate material by a first thermal treatment or implanting a non-doping material forming vacancies in the substrate material.

17. The method of claim 1, wherein forming the doped implant regions comprises forming at least one of source/drain implant regions, contact implant regions, lightly doped drain regions, or pocket implant regions on opposed sides of the at least one patterned gate stack.

18. The method of claim 1, wherein the second material comprises a p-dopant.

19. The method of claim 1, wherein the second material comprises both a p-dopant and an n-dopant implanted to form a CMOS integrated circuit, wherein implanting the second material comprises:
providing a mask on first substrate surface regions and implanting one of the p-dopant and the n-dopant into second substrate regions different from the first substrate surface regions and removing the mask from the first substrate surface regions; and
providing a further mask on the second substrate surface regions and implanting the other one of the p-dopant and the n-dopant into the first substrate regions.

20. An integrated circuit comprising:
a substrate having a substrate surface and comprising a substrate material;
at least one patterned gate stack over the substrate;
a buried getter layer arranged in the substrate at a depth below the substrate surface and passing beneath the patterned gate stack,
wherein the buried getter layer comprises a getter material arranged in the substrate material, and
wherein the getter layer continuously extends in a lateral direction beneath the patterned gate stack; and
doped implant regions arranged in the substrate on opposed sides of the at least one patterned gate stack, the doped implant regions extending from the substrate surface into the substrate.

21. The integrated circuit of claim 20, wherein the concentration of the getter material in the getter layer, in the lateral direction, comprises a local minimum at a centered position beneath the patterned gate stack.

22. The integrated circuit of claim 20, wherein a concentration of the getter material at the local minimum is larger than zero.

23. The integrated circuit of claim 20, wherein the getter material is carbon.

24. The integrated circuit of claim 20, wherein the getter material is oxygen or fluorine.

25. The integrated circuit of claim 20, wherein the buried getter layer, laterally outside the patterned gate stack, comprises the maximum concentration of the getter material which maximum concentration is between 1×10¹⁹/cm³ and 5×10²⁰/cm³.

26. The integrated circuit of claim 20, wherein the getter layer is arranged at a distance from the substrate surface, the distance being larger than twice a width of the patterned gate stack but smaller than six times the width of the patterned gate stack.

27. The integrated circuit of claim 20, wherein the substrate comprises a first material between the substrate surface and the buried getter layer, wherein the getter material of the buried getter layer is a material different from the substrate material and from the first material.

28. The integrated circuit of claim 27, wherein the first material comprises at least one of germanium, silicon, argon, krypton, xenon, or another material which does not form n-doped or p-doped regions when implanted in the substrate.

29. The integrated circuit of claim 20, wherein the doped implant regions comprise at least one of source/drain implant regions, contact implant regions, lightly doped drain regions, or pocket implant regions.

30. The integrated circuit of claim 20, wherein the doped implant regions extend from the substrate surface into the substrate to a substrate depth smaller than the depth of the buried getter layer.

31. The integrated circuit of claim 20, wherein the buried getter layer separates the substrate material arranged between the substrate surface and the buried getter layer from end-of-range-defects.

32. The integrated circuit of claim 20, wherein the substrate comprises at least one transistor formed at the at least one patterned gate stack.

33. A method of forming an integrated circuit, the method comprising:
forming at least one patterned gate stack on a substrate comprising a substrate surface;
implanting a first material in the substrate to form an amorphous substrate region and implanting a getter material to form a getter region within the amorphous substrate region;
implanting a second material to form doped implant regions extending from the substrate surface into the substrate; and
applying a thermal treatment to recrystallize the substrate material and/or to activate the second material in the doped implant regions.

34. The method of claim 33, wherein the substrate is amorphised to an amorphisation depth larger than a depth of the getter region and wherein the getter material comprises one of carbon, oxygen or fluorine.

35. The method of claim 33, wherein the amorphous substrate region is recrystallized by the thermal treatment prior to implanting the second material.

36. The method of claim 33, wherein a non-doping material is implanted into the substrate after recrystallizing the amorphous substrate region, prior to implanting the second material.

37. A method of forming an integrated circuit, the method comprising:
forming at least one patterned gate stack on a substrate and forming a getter region in the substrate by implanting a getter material;
forming an amorphous substrate region in the substrate by implanting a first material in the substrate, thereby amorphizing the getter region;
forming doped implant regions extending from a surface of the substrate into the substrate by implanting a second material; and
performing at least one thermal treatment.

38. The method of claim 37, wherein the second material is implanted between a first thermal treatment and a further, second thermal treatment.

39. An integrated circuit comprising:
at least one patterned gate stack arranged on a substrate;
a buried getter layer arranged in the substrate passing in a distance below the patterned gate stack;
doped implant regions arranged in the substrate on opposed sides of the patterned gate stack, the doped implant regions being arranged adjacent to a substrate surface supporting the patterned gate stack; and
the buried getter layer comprising a getter material, wherein a concentration of the getter material, in a lateral direction, comprises a local minimum arranged at a laterally centered position beneath the patterned gate stack, the concentration of the getter material at the local minimum being larger than zero.

40. The integrated circuit of claim 39, wherein the getter material is one of carbon, oxygen and fluorine.

41. The integrated circuit of claim 39, wherein the getter layer is arranged at a distance from the substrate surface, the distance being larger than twice a width of the patterned gate stack but smaller than six times the width of the patterned gate stack.

42. The integrated circuit of claim 39, wherein the doped implant regions comprises at least one of source/drain implant regions, lightly doped drain regions, pocket implant regions or contact implant regions.

43. The integrated circuit of claim 39, wherein the substrate comprises at least one transistor formed at the patterned gate stack, the transistor being a transistor of a logic circuit of a CMOS device.

44. The integrated circuit of claim 39, wherein the logic circuit is a support region of a volatile or a non-volatile memory device.

45. An integrated circuit comprising:
a substrate having a substrate surface and comprising a substrate material;
at least one patterned gate stack having a width in lateral direction parallel to the substrate surface;
a buried getter layer arranged in the substrate at a distance from the substrate surface and passing beneath the patterned gate stack; and
doped implant regions arranged in the substrate on opposed sides of the at least one patterned gate stack,
wherein the distance of the buried getter layer from the substrate surface, in a direction perpendicular to the substrate surface, is larger than the width of the patterned gate stack in a lateral direction.

46. The integrated circuit of claim 45, wherein the distance of the buried getter layer from the substrate surface is between twice and four times a width of the patterned gate stack.

47. The integrated circuit of claim 45, wherein the patterned gate stack comprises an extension in a vertical direction of between 0.20 and 1.2 times the distance of the buried getter layer from the substrate surface.

48. The integrated circuit of claim 45, wherein the relative amount of the extension of the patterned gate stack in the vertical direction relative to the width of the patterned gate stack defines an aspect ratio, the aspect ratio ranging between 1 and 4.

49. The integrated circuit of claim 45, wherein the buried getter layer comprises a getter material arranged in the substrate, the getter material being arranged deeper in the substrate than the doped implant regions.

50. The integrated circuit of claim 45, wherein a concentration of the getter material, in the lateral direction, comprises a local minimum arranged at a laterally centered position beneath the patterned gate stack, the concentration of the getter material at the local minimum being larger than zero.
